(19) United States
(12) Patent Application Publication
(10) Pub. No.: US 2026/0282320 A1
(43) Pub. Date: Sep. 17, 2026

(54) METHOD OF MANUFACTURING SEMICONDUCTOR DEVICE

(71) Applicant: SAMSUNG ELECTRONICS CO., LTD., Suwon-si (KR)

(72) Inventors: Jiyun LEE, Suwon-si (KR); Jongwoo PARK, Suwon-si (KR); Taejin BAE, Suwon-si (KR); Chanho LEE, Suwon-si (KR); Sangil HAN, Suwon-si (KR); Jinwoo HAN, Suwon-si (KR)

(73) Assignee: SAMSUNG ELECTRONICS CO., LTD., Suwon-si (KR)

(21) Appl. No.: 19/366,949

(22) Filed: Oct. 23, 2025

(30) Foreign Application Priority Data
Mar. 17, 2025 (KR) 10-2025-0034140

(51) Int. Cl. H10B 12/00

(52) U.S. Cl. CPC H10B 12/05; H10B 12/30

(57) ABSTRACT

A method of manufacturing a semiconductor device is provided. A laminated stack of alternately stacked mold sacrificial layers and single crystal semiconductor layers is formed on an interface area of a substrate having a cell array area. First holes are formed through a cover insulating layer, and the mold sacrificial layers are removed to create first gaps. A first liner surrounds the single crystal semiconductor layers, and a second liner fills the first gaps. A gap fill insulating layer is formed, second holes are opened, and portions of the liners and single crystal semiconductor layers facing the holes are removed. A pad layer is formed at the removal location, and the second holes are filled with insulating material. The pad layer has a step-like structure parallel to the substrate surface, a constant width in a perpendicular direction, and is connected to a word line in the cell array area.

### CROSS-REFERENCE TO RELATED APPLICATION

This application is based on and claims priority under 35 U.S.C. § 119 to Korean Patent Application No. 10-2025-0034140, filed on Mar. 17, 2025, with the Korean Intellectual Property Office, the disclosure of which is incorporated herein by reference in its entirety.

### BACKGROUND

The present inventive concept relates to a method of manufacturing a semiconductor device. More specifically, the inventive concept relates to a method of manufacturing a semiconductor device having a three-dimensional structure.

To provide superior performance and cost-effectiveness, there is a demand to increase the integration density of memory devices. In particular, the integration density of memory devices is an important factor in determining the economic feasibility of a product. Since the integration density of two-dimensional memory devices is mainly determined by the area occupied by unit memory cells, it is greatly affected by the level of fine pattern formation technology. However, since expensive equipment is required to form fine patterns and the area of a chip die is limited, the integration of two-dimensional memory devices is still limited, although increasing. Accordingly, vertical semiconductor devices with a three-dimensional structure are required.

### SUMMARY

The inventive concept provides a semiconductor device that provides stable performance and improved reliability.

In addition, the objective to be solved by the inventive concept is not limited to the above-mentioned ones, and other objectives will be clearly understood by those skilled in the art from the description below.

The inventive concept provides a method of manufacturing a semiconductor device as below.

According to an aspect of the inventive concept, there is provided a method of manufacturing a semiconductor device, the method including forming a laminated stack including a plurality of alternately stacked mold sacrificial layers and single crystal semiconductor layers, on an interface area of a substrate including a cell array area and the interface area disposed on at least one side of the cell array area, forming a cover insulating layer covering the laminated stack, and then removing a portion of the cover insulating layer, to form a plurality of first holes, forming a plurality of first gaps between the plurality of single crystal semiconductor layers by removing the plurality of mold sacrificial layers through the plurality of first holes, and forming a first liner surrounding the plurality of single crystal semiconductor layers, forming a second liner on the first liner, to fill the first gaps, forming a gap fill insulating layer surrounding the plurality of first holes and the laminated stack, and removing a portion of the gap fill insulating layer to form a plurality of second holes, removing portions of the single crystal semiconductor layers, the portions facing side walls of the plurality of second holes, forming a pad layer at a location from which the single crystal semiconductor layers are removed, and

filling the plurality of second holes with an insulating material, wherein the pad layer has a step-like structure in a first direction parallel to an upper surface of the substrate, has a constant width in a second direction intersecting the first direction, and is connected to a word line arranged in the cell array area.

According to another aspect of the inventive concept, there is provided a method of manufacturing a semiconductor device, the method including forming a laminated stack including a plurality of alternately stacked mold sacrificial layers and single crystal semiconductor layers, on an interface area of a substrate including a cell array area and the interface area disposed on at least one side of the cell array area, forming a cover insulating layer covering the laminated stack, and then removing a portion of the cover insulating layer, to form a plurality of first holes, removing the plurality of mold sacrificial layers through the plurality of first holes and forming a liner surrounding the plurality of single crystal semiconductor layers and spaces between the plurality of single crystal semiconductor layers, forming a gap fill insulating layer surrounding the plurality of first holes and the laminated stack, and removing a portion of the gap fill insulating layer to form a plurality of second holes, removing portions of the single crystal semiconductor layers, the portions facing side walls of the plurality of second holes, forming a pad layer at a location from which the single crystal semiconductor layers are removed, and

filling the plurality of second holes with an insulating material, wherein the pad layer has a step-like structure in a first direction parallel to an upper surface of the substrate, has a constant width in a second direction intersecting the first direction, and is connected to a word line arranged in the cell array area.

According to another aspect of the inventive concept, there is provided a method of manufacturing a semiconductor device, the method including forming a laminated stack including a plurality of alternately stacked mold sacrificial layers and single crystal semiconductor layers, on an interface area of a substrate including a cell array area and the interface area disposed on at least one side of the cell array area, forming a cover insulating layer covering the laminated stack, and then removing a portion of the cover insulating layer, to form a plurality of first holes, forming a plurality of first gaps between the plurality of single crystal semiconductor layers by removing the plurality of mold sacrificial layers through the plurality of first holes, and forming a first liner surrounding the plurality of single crystal semiconductor layers, forming a second liner on the first liner, to fill the first gaps, forming a gap fill insulating layer surrounding the plurality of first holes and the laminated stack, and forming a plurality of second holes by removing a portion of the gap fill insulating layer up to a first level higher than a level of an upper surface of the substrate, removing at least some portions of the first and second liners, the portions facing side walls of the plurality of second holes, and removing the single crystal semiconductor layers arranged at a level equal to or higher than the first level, forming a pad layer at a location from which the single crystal semiconductor layers are removed, and

filling the plurality of second holes with an insulating material, wherein the pad layer has a step-like structure in a first direction parallel to the upper surface of the substrate, has a constant width in a second direction intersecting the first direction, and is connected to a word line arranged in the cell array area.

The inventive concept provides a semiconductor device below.

According to another aspect of the inventive concept, there is provided a semiconductor device including a substrate including a cell array area and an interface area disposed on at least one side of the cell array area, a plurality of word lines horizontally extending from the cell array area to the interface area of the substrate, a plurality of word line pad portions arranged in the interface area of the substrate, respectively connected to the plurality of word lines, and arranged to overlap each other in a vertical direction perpendicular to an upper surface of the substrate, and an insulation liner surrounding an upper surface, a lower surface, and one side surface of each of the plurality of word line pad portions, wherein the plurality of word line pad portions have a step-like structure in a first direction parallel to the upper surface of the substrate, have a constant width in a second direction intersecting the first direction, and the other side surface opposite the one side surface faces an insulating structure extending in the vertical direction.

### BRIEF DESCRIPTION OF THE DRAWINGS

Embodiments will be more clearly understood from the following detailed description taken in conjunction with the accompanying drawings in which:

FIG. 1 is a schematic diagram illustrating a semiconductor device according to embodiments;

FIG. 2 is a schematic enlarged plan view of region EX1 of FIG. 1;

FIG. 3 is a cross-sectional view taken along line A-A′ of FIG. 2;

FIG. 4 is a cross-sectional view taken along line B-B′ of FIG. 3;

FIG. 5A illustrates a schematic plan view of a semiconductor device according to an embodiment;

FIG. 5B is a cross-sectional view taken along line C-C′ of FIG. 5A;

FIGS. 6 to 14 are cross-sectional views schematically illustrating a method of manufacturing a semiconductor device, according to an embodiment;

FIG. 15 is an enlarged cross-sectional view of region EX2 of FIG. 14;

FIGS. 16, 17, and 19 are cross-sectional views schematically illustrating a method of manufacturing a semiconductor device, according to an embodiment; and

FIG. 18 is an enlarged view of region EX3 of FIG. 17.

### DETAILED DESCRIPTION OF THE EMBODIMENTS

Hereinafter, embodiments will be described in detail with reference to the attached drawings. The same reference numerals are used for identical components in the drawings, and repeated descriptions of these are omitted.

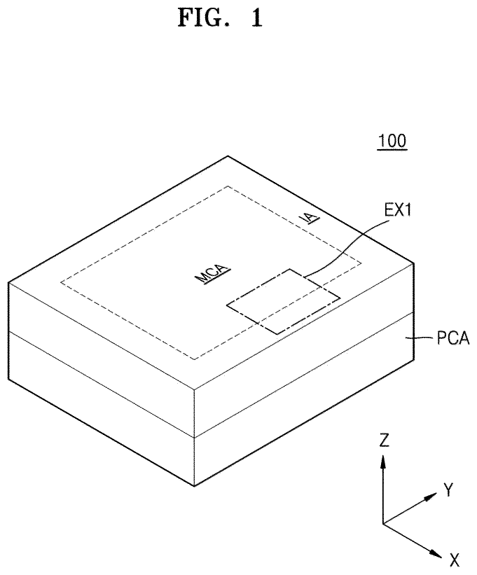

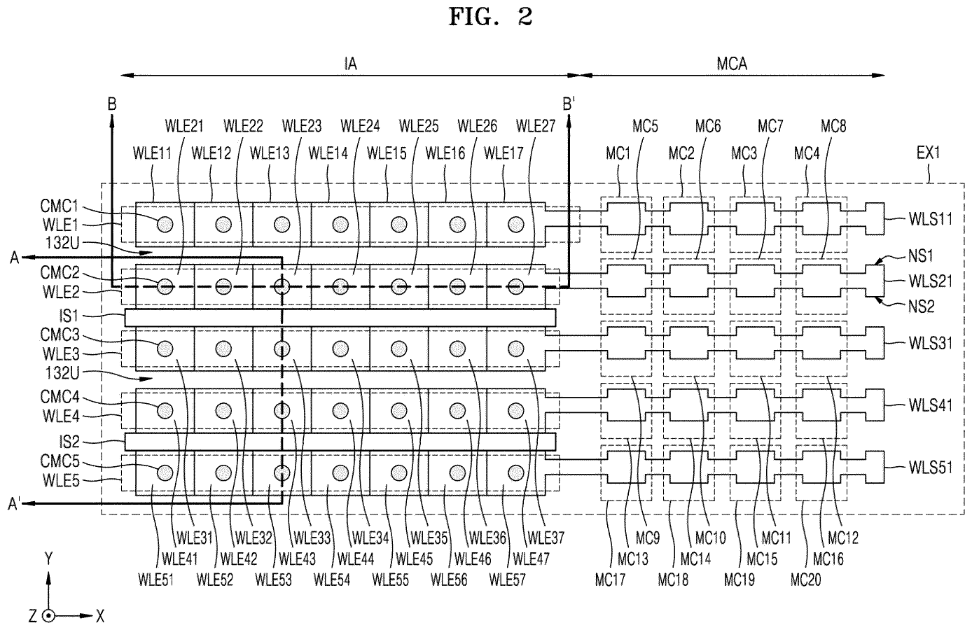

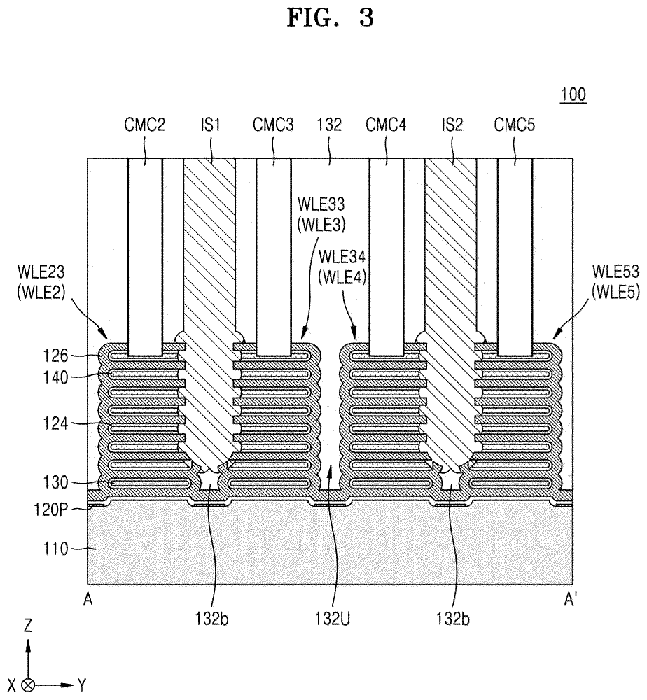

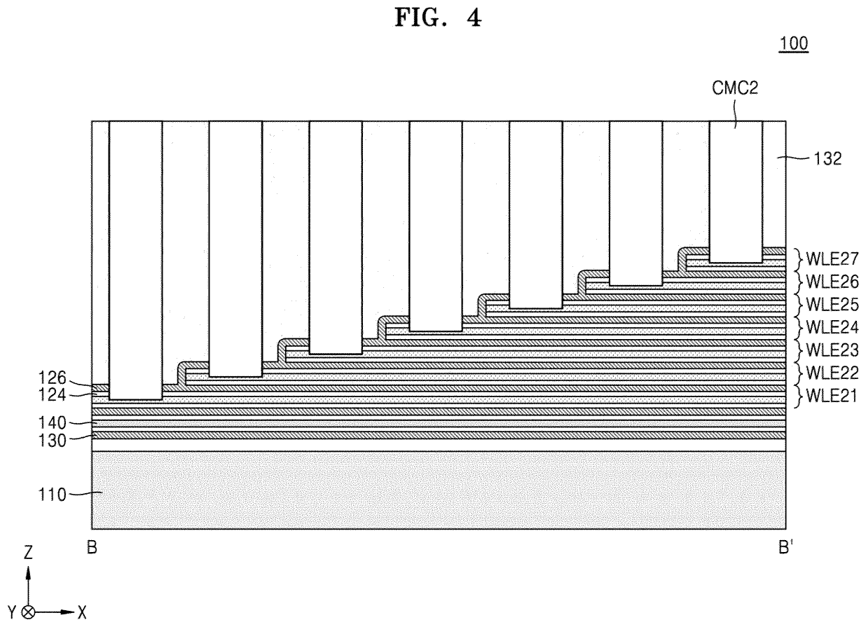

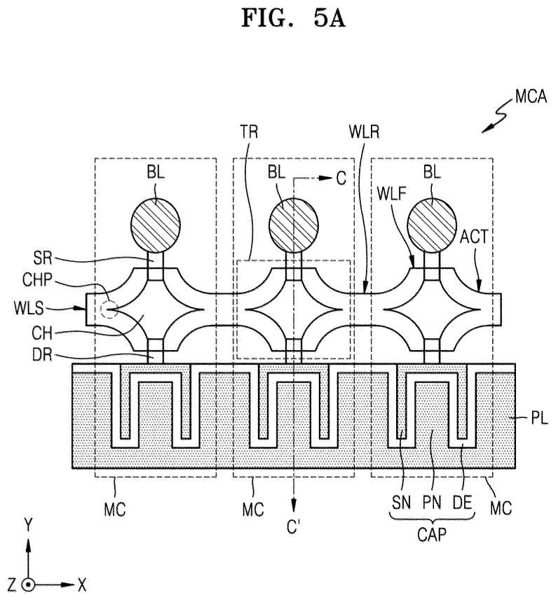

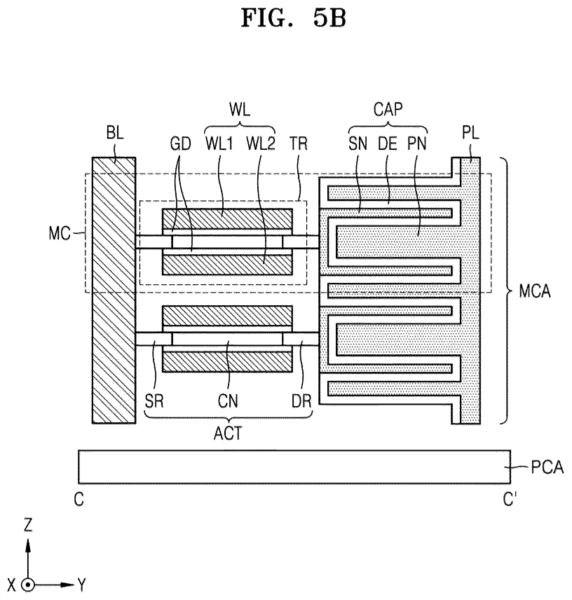

FIG. 1 is a schematic diagram illustrating a semiconductor device 100 according to embodiments. FIG. 2 is a schematic enlarged plan view of region EX1 of FIG. 1. FIG. 3 is a cross-sectional view taken along line A-A′ of FIG. 2, and FIG. 4 is a cross-sectional view taken along line B-B′ of FIG. 2. FIG. 5A illustrates a schematic plan view of a cell array area MCA of the semiconductor device 100, and FIG. 5B is a cross-sectional view taken along line C-C′ of FIG. 5A.

Referring to FIGS. 1, 2, 3, 4, 5A, and 5B, the semiconductor device 100 may include the cell array area MCA and a peripheral circuit area PCA arranged at different vertical levels. The peripheral circuit area PCA and the cell array area MCA may overlap each other in a vertical direction. For example, the cell array area MCA may be arranged on the peripheral circuit area PCA as illustrated in FIG. 1, and the semiconductor device 100 may have a cell over periphery (COP) structure. The cell array area MCA may be surrounded planarly by an interface area IA.

In some embodiments, the cell array area MCA may be a memory cell area of a dynamic random-access memory (DRAM) device, and the peripheral circuit area PCA may be a core area or a peripheral circuit area of the DRAM device. For example, the peripheral circuit area PCA may include peripheral circuit transistors (not shown) for transmitting signals and/or power to a memory cell array included in the cell array area MCA. In embodiments, the peripheral circuit transistors may configure various circuits such as a command decoder, control logic, an address buffer, a row decoder, a column decoder, a sense amplifier, and a data input/output circuit.

The cell array area MCA may include a plurality of memory cells MC. The cell array area MCA may include a three-dimensional array of memory cells MC. The three-dimensional array of memory cells MC may include a column array and a row array. FIG. 5A illustrates a row array of memory cells MC arranged horizontally in a first direction (X direction), and FIG. 5B illustrates a column array of memory cells MC stacked in a third direction (Z direction). In other embodiments, the cell array area MCA may further include a row array of memory cells MC arranged horizontally in a second direction (Y direction).

The cell array area MCA may include a word line stack WLS, a plurality of bit lines BL, a plurality of transistors TR, and a plurality of capacitors CAP. A plurality of cell array areas MCA may share one word line stack WLS. Each individual memory cell MC may include a bit line BL, a transistor TR, and a capacitor CAP.

In embodiments, each transistor TR may include an active region ACT and a word line WL, and the word line WL may include a double word line structure. For example, the double word line structure of the word line WL may include a pair of a first word line WL1 and a second word line WL2. The first word line WL1 and the second word line WL2 may be perpendicularly opposite to each other in the third direction (Z direction) with the active region ACT therebetween, but the inventive concept is not limited thereto.

In embodiments, each capacitor CAP may include a storage node SN, a dielectric layer DE, and a plate node PN.

The bit line BL may have a pillar shape extending in the third direction (Z direction). The active region ACT may have a bar shape extending in the second direction (Y direction) intersecting the third direction (Z direction). The word line WL may have a line shape extending in the first direction (X direction) intersecting the second direction (Y direction) and the third direction (Z direction). The plate nodes PN of the capacitors CAP may be interconnected to each other and connected to a plate line PL.

In embodiments, the bit line BL may be vertically oriented in the third direction (Z direction). The bit line BL may be referred to as a vertically oriented bit line or a pillar bit line. The bit line BL may include a conductive material. The bit line BL may include a silicon-based material, a metal-based material, or a combination thereof. The bit line BL may include silicon, metal, metal nitride, metal silicide, or a combination thereof. The bit line BL may include polysilicon, titanium nitride, tungsten, or a combination thereof. For example, the bit line BL may include polysilicon or titanium nitride (TiN) doped with n-type impurities. The bit line BL may include a TiN/W stack including titanium nitride and tungsten on titanium nitride.

The word line WL may extend in the second direction (Y direction), and the active region ACT may extend in the second direction (Y direction). The active region ACT may be arranged horizontally in the second direction (Y direction) from the bit line BL. A gate insulating layer GD may be formed on an upper surface and a lower surface of the active region ACT.

The transistor TR may include a cell transistor and have the word line WL. In the word line WL, a same voltage may be applied to the first word line WL1 and the second word line WL2. For example, the first word line WL1 and the second word line WL2 may form a pair, and a same word line driving voltage may be applied to each of the first word line WL1 and the second word line WL2. In some embodiments, the first word line WL1 and the second word line WL2 may include a merged portion. For example, the word line WL may be of a gate all around (GAA) type that extends in the first horizontal direction (X direction) and surrounds a channel region CH. In some embodiments, the first word line WL1 and the second word line WL2 may be merged in a pad portion for voltage application (see a pad layer 140 in FIG. 3).

The active region ACT may include a semiconductor material. The active region ACT may include a silicon-containing layer or a silicon germanium-containing layer. For example, the active region ACT may include silicon, single crystal silicon, doped polysilicon, undoped polysilicon, amorphous silicon, silicon germanium, or combinations thereof. In another embodiment, the active region ACT may include nanowires or nanosheets, and the nanowires and nanosheets may include a semiconductor material. In another embodiment, the active region ACT may include an oxide semiconductor material, such as indium gallium zinc oxide (IGZO). The active region ACT may include the channel region CH, a first source/drain region SR, and a second source/drain region DR. In embodiments, the first source/drain region SR and the second source/drain region DR may be formed within the active region ACT by ion implantation or plasma doping of impurities. The channel region CH may include channel protrusions CHP that are symmetrical to each other in the first direction (X direction). The channel protrusions CHP may vertically overlap the first and second word lines WL1 and WL2.

In some embodiments, each of the first and second word lines WL1 and WL2 may include notched side walls facing each other. The individual notched side walls may include flat surfaces WLF and recessed surfaces WLR. The flat surfaces WLF and the recessed surfaces WLR may be alternately repeated in the first direction (X direction). The flat surfaces WLF may be flat side walls, and the recessed surfaces WLR may be recessed side walls. The flat surfaces WLF may vertically overlap with the first and second source/drain regions SR, DR. The recessed surfaces WLR may not overlap the first and second source/drain regions SR, DR. The flat surfaces WLF may face each other in the second direction (Y direction). The recessed surfaces WLR may face each other in the second direction (Y direction). In some embodiments, the recessed surfaces WLR may have a round shape.

The gate insulating layer GD may include a silicon oxide, a silicon nitride, a metal oxide, a metal oxynitride, a metal silicate, a high-k material, a ferroelectric material, an antiferroelectric material, or a combination thereof. The gate insulating layer GD may include SiO₂, Si₃N₄, HfO₂, Al₂O₃, ZrO₂, AlON, HfON, HfSiO, HfSiON, or HfZrO.

The word line WL may include a metal, a metal mixture, or a semiconductor material. The word line WL may include titanium nitride, tungsten, polysilicon, or a combination thereof. For example, the word line WL may include a TiN/W stack in which titanium nitride and tungsten are sequentially stacked. The word line WL may include an n-type work function material or a p-type work function material. The n-type work function material may have a low work function of 4.5 eV or less, and the p-type work function material may have a high work function of 4.5 eV or more.

The capacitor CAP may be arranged horizontally from the transistor TR in the second direction (Y direction). The capacitor CAP may include the storage node SN extending horizontally from the active region ACT in the second direction (Y direction). The capacitor CAP may further include the dielectric layer DE and the plate node PN on the storage node SN. The storage node SN, the dielectric layer DE, and the plate node PN may be arranged horizontally in the second direction (Y direction). The storage node SN may have a horizontally oriented cylinder-shape. The dielectric layer DE may conformally cover an inner cylindrical wall and an outer cylindrical wall of the storage node SN. The plate node PN may have a shape extending from the inner cylindrical wall and the outer cylindrical wall of the storage node SN on the dielectric layer DE. The plate node PN may be connected to the plate line PL. The storage node SN may be electrically connected to the active region ACT.

In embodiments, the storage node SN may have a three-dimensional structure, and the storage node SN of the three-dimensional structure may include a horizontal three-dimensional structure oriented in the second direction (Y direction). As an example of the three-dimensional structure, the storage node SN may have a cylindrical shape. In another embodiment, the storage node SN may be pillar-shaped, although the inventive concept is not limited thereto.

The storage node SN and the plate node PN may each include a metal, a precious metal, metal nitride, a conductive metal oxide, a conductive precious metal oxide, metal carbide, metal silicide, or a combination thereof. For example, the storage node SN and the plate node PN may each include Ti, TiN, Ta, TaN, W, WN, Ru, RuO₂, Ir, IrO₂, Pt, Mo, MoO, a TiN/W stack, and a WN/W stack. The plate node PN may be a stack of TiN/SiGe/WN. In a TiN/SiGe/WN stack, SiGe may be a gap fill material filling the inside of the cylinder of the storage node SN on TiN, TiN may act as the plate node PN of the capacitor CAP, and WN may be a low-resistance material.

The dielectric layer DE may be referred to as a capacitor dielectric layer. The dielectric layer DE may include a silicon oxide, a silicon nitride, a high-k material, or a combination thereof. The high-k material may have higher permittivity than a silicon oxide. In some embodiments, the high-k material may have a permittivity of greater than about 20. The high-k material may include a hafnium oxide, zirconium oxide, aluminum oxide, lanthanum oxide, titanium oxide, tantalum oxide, niobium oxide, or strontium titanium oxide. In another embodiment, the dielectric layer DE may include a composite layer including two or more layers of the high-k materials described above.

In some embodiments, the capacitor CAP may include a Metal-Insulator-Metal (MIM) capacitor, although the inventive concept is not limited thereto. The capacitor CAP may be rearranged by another data storage element. For example, the data storage element may include a phase change material, a magnetic tunnel junction (MTJ), or a variable resistance material.

Active regions ACT stacked in the third direction (Z direction) may contact one bit line BL in common. Neighboring active regions ACT in the first direction (X direction) may share the word line WL. The capacitors CAP may be respectively connected to the active regions ACT. The capacitors CAP may share one plate line PL. In some embodiments, each of the active regions ACT may be thinner than the first and second word lines WL1 and WL2 of the word line WL.

The cell array area MCA may include a plurality of word line stacks WLS. Each word line stack WLS may include a plurality of word lines WL vertically stacked in the third direction (Z direction). Each word line WL may include a pair of the first word line WL1 and the second word line WL2.

The interface area IA may be an area where contacts, vias, wiring, etc. are formed for electrical connection between a memory cell array included in the cell array area MCA and a peripheral circuit transistor included in the peripheral circuit area PCA.

The peripheral circuit area PCA may include a substrate 110 and peripheral circuit transistors disposed on the substrate 110. The peripheral circuit transistors may be located at a lower level than the cell array area MCA. As described above, this may be referred to as a COP structure. The peripheral circuit transistors may include at least one control circuit for driving the cell array area MCA. At least one control circuit of the peripheral circuit transistors may include an n-channel transistor, a p-channel transistor, a complementary metal oxide semiconductor (CMOS) circuit, or a combination thereof. The peripheral circuit area PCA may include a material suitable for semiconductor processing. The peripheral circuit area PCA may include at least one of a conductive material, an insulating material, and a semiconductor material.

The substrate 110 may include silicon, for example, single crystal silicon, polycrystalline silicon, or amorphous silicon. In some other embodiments, the substrate 110 may include at least one selected from Ge, SiGe, SiC, GaAs, InAs, and InP. A peripheral circuit transistor may be arranged on the active region ACT of the substrate 110. The peripheral circuit transistor may include at least one of a planar transistor, a fin field-effect transistor (FinFET), a multi-bridge channel transistor, and a buried channel array transistor.

Referring to FIG. 2, the semiconductor device 100 may include the cell array area MCA and the interface area IA. The cell array area MCA may include a plurality of memory cells MC1, MC2, MC3, MC4, MC5, MC6, MC7, MC8, MC9, MC10, MC11, MC12, MC13, MC14, MC15, MC16, MC17, MC18, MC19, and MC20 and a plurality of word line stacks WLS11, WLS21, WLS31, WLS41, and WLS51. The memory cells MC1, MC2, MC3, MC4 of a first group may share a first word line stack WLS11. The memory cells MC5, MC6, MC7, MC8 of a second group may share a second word line stack WLS21. The memory cells MC9, MC10, MC11, MC12 of a third group may share a third word line stack WLS31. The memory cells MC13, MC14, MC15, MC16 of a fourth group may share a fourth word line stack WLS41. The memory cells MC17, MC18, MC19, MC20 of a fifth group may share a fifth word line stack WLS51. The first to fifth word line stacks WLS11, WLS21, WLS31, WLS41, WLS51 may each include first and second notched side walls NS1 and NS2. The first and second notched side walls NS1, NS2 may each include a plurality of flat surfaces WLF and a plurality of recessed surfaces WLR.

Each of the word line stacks WLS11, WLS21, WLS31, WLS41, WLS51 may include a plurality of word lines WL. For example, each of the word line stacks WLS11, WLS21, WLS31, WLS41, WLS51 may include the plurality of word lines WL stacked in the third direction (Z direction).

The word line stacks WLS11, WLS21, WLS31, WLS41, WLS51 may extend from the cell array area MCA to the interface area IA. That is, the word line stacks WLS11, WLS21, WLS31, WLS41, WLS51 may respectively include first to fifth word line edge portions WLE1, WLE2, WLE3, WLE4, and WLE5 located in the interface area IA.

Referring to FIG. 4, the first to fifth word line edge portions WLE1, WLE2, WLE3, WLE4, and WLE5 may each have a step-like structure including a plurality of word line pad portions. A first word line edge portion WLE1 may include first to seventh word line pad portions WLE11, WLE12, WLE13, WLE14, WLE15, WLE16, and WLE17. A second word line edge portion WLE2 may include first to seventh word line pad portions WLE21, WLE22, WLE23, WLE24, WLE25, WLE26, WLE27. A third word line edge portion WLE3 may include first to seventh word line pad portions WLE31, WLE32, WLE33, WLE34, WLE35, WLE36, WLE37. A fourth word line edge portion WLE4 may include first to seventh word line pad portions WLE41, WLE42, WLE43, WLE44, WLE45, WLE46, WLE47. A fifth word line edge portion WLE5 may include first to seventh word line pad portions WLE51, WLE52, WLE53, WLE54, WLE55, WLE56, WLE57. A horizontal length of the semiconductor device 100 may gradually decrease from the first word line pad portions WLE11, WLE21, WLE31, WLE41, WLE51 of a lowest level to the seventh word line pad portions WLE17, WLE27, WLE37, WLE47, WLE57 of a highest level. Here, the horizontal length of the semiconductor device 100 may refer to a length thereof in the first direction (X direction).

The semiconductor device 100 may further include first and second insulating structures IS1, IS2. The first insulating structure IS1 may be arranged between the second word line edge portion WLE2 and the third word line edge portion WLE3, and the second insulating structure IS2 may be arranged between the fourth word line edge portion WLE4 and the fifth word line edge portion WLE5. A lower gap fill insulating layer 132U may be arranged between the first word line edge portion WLE1 and the second word line edge portion WLE2 and between the third word line edge portion WLE3 and the fourth word line edge portion WLE4. The first insulating structure IS1 and the second insulating structure IS2 may be spaced apart from each other in the second direction (Y direction). The first insulating structure IS1 and the second insulating structure IS2 may each extend in the first direction (X direction). The first direction (X direction), the second direction (Y direction), and the third direction (Z direction) may intersect with each other.

The first and second insulating structures IS1 and IS2 may each include an insulating material. For example, the first and second insulating structures IS1 and IS2 may each include a silicon oxide, a silicon carbon oxide, a silicon nitride, a low-k material, or a combination thereof. The first and second insulating structures IS1 and IS2 may include isolation layers that mutually isolate the second word line edge portion WLE2 from the third word line edge portion WLE3 and the fourth word line edge portion WLE4 from the fifth word line edge portion WLE5. Additionally, the first and second insulating structures IS1 and IS2 may be supporters supporting the first to fifth word line edge portions WLE1, WLE2, WLE3, WLE4, and WLE5.

The first to seventh word line pad portions WLE11 to WLE17, WLE21 to WLE27, WLE31 to WLE37, WLE41 to WLE47, WLE51 to WLE57 may each include the first word line WL1, the second word line WL2, and a pad (not shown). The pad may be arranged between the first word line WL1 and the second word line WL2 in the third direction (Z direction). The first word line WL1 and the second word line WL2 may be electrically connected to each other via the pad. The first word line WL1, the second word line WL2, and the pad may include a same material as each other. The pad may include a metal base material. The pad may include titanium nitride, tungsten or a combination thereof.

The first to seventh word line pad portions WLE11 to WLE17, WLE21 to WLE27, WLE31 to WLE37, WLE41 to WLE47, WLE51 to WLE57 may each include a conductive material. The first to seventh word line pad portions WLE11 to WLE17, WLE21 to WLE27, WLE31 to WLE37, WLE41 to WLE47, WLE51 to WLE57 may each include a metal, a metal mixture, or a semiconductor material. The first to seventh word line pad portions WLE11 to WLE17, WLE21 to WLE27, WLE31 to WLE37, WLE41 to WLE47, WLE51 to WLE57 may each include titanium nitride, tungsten, polysilicon, or a combination thereof. For example, the first to seventh word line pad portions WLE11 to WLE17, WLE21 to WLE27, WLE31 to WLE37, WLE41 to WLE47, WLE51 to WLE57 may each include a TiN/W stack in which titanium nitride and tungsten are sequentially stacked.

Referring to FIGS. 3 and 4, first to fifth contact plugs CMC1, CMC2, CMC3, CMC4, CMC5 may be formed on the first to seventh word line pad portions WLE11 to WLE17, WLE21 to WLE27, WLE31 to WLE37, WLE41 to WLE47, WLE51 to WLE57. The first to fifth contact plugs CMC1, CMC2, CMC3, CMC4, CMC5 may each include a conductive material and may be connected to the first to seventh word line pad portions WLE11 to WLE17, WLE21 to WLE27, WLE31 to WLE37, WLE41 to WLE47, WLE51 to WLE57. The first to fifth contact plugs CMC1, CMC2, CMC3, CMC4, CMC5 may be electrically connected to the word lines WL through the first to seventh word line pad portions WLE11 to WLE17, WLE21 to WLE27, WLE31 to WLE37, WLE41 to WLE47, WLE51 to WLE57. Referring to FIG. 2, the first to fifth contact plugs CMC1, CMC2, CMC3, CMC4, CMC5 spaced apart from each other in the first horizontal direction (X direction) and the second horizontal direction (Y direction) and arranged in groups of seven are illustrated, but this is merely an example and the number and positions of the contact plugs are not limited thereto.

Although omitted for convenience of illustration, the first to fifth contact plugs CMC1, CMC2, CMC3, CMC4, CMC5 may further include a barrier layer (not shown) surrounding the first to fifth contact plugs CMC1, CMC2, CMC3, CMC4, CMC5.

Since the first to fifth word line edge portions WLE1, WLE2, WLE3, WLE4, WLE5 have a step-like structure in the first horizontal direction (X direction), the vertical (Z direction) lengths of the first to fifth contact plugs CMC1, CMC2, CMC3, CMC4, CMC5 spaced apart from each other in the first horizontal direction (X direction) may be different from each other (see FIG. 4). However, vertical lengths of the first to fifth contact plugs CMC1, CMC2, CMC3, CMC4, CMC5 in the vertical direction (Z direction), the contact plugs being spaced apart from each other in the second horizontal direction (Y direction), may be equal to each other (see FIG. 3).

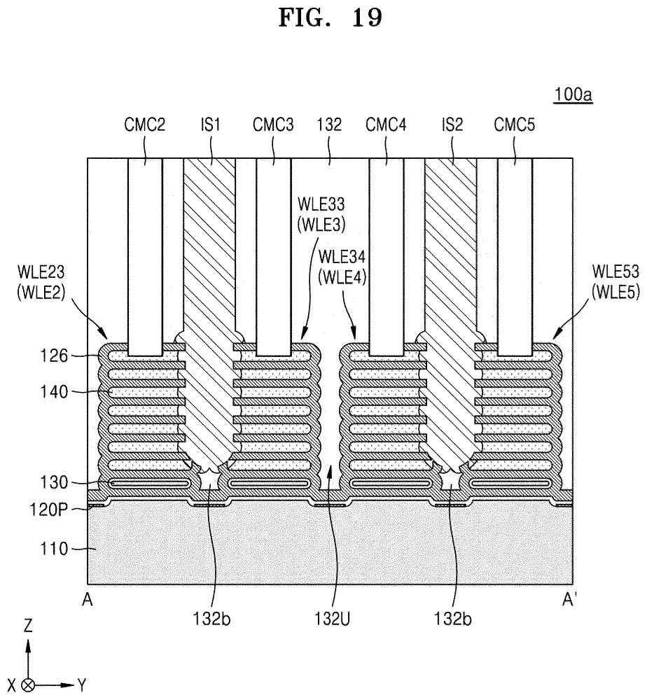

Referring to FIG. 3, each of the third word line pad portions WLE23, WLE33, WLE43, WLE53 may include pad layers 140 stacked in the vertical direction (Z direction). A first liner 124 and a second liner 126 may have a structure that surrounds each pad layer 140 in a ‘C’ shape, but in some other embodiments, a liner surrounding the pad layers 140 may be formed as a single layer (see a semiconductor device 100a of FIG. 19). For example, the third word line pad portions WLE23, WLE33, WLE43, WLE53 may each be an end portion of the word line WL of FIG. 5B.

An exposed surface of the pad layer 140, which is not surrounded by the first liner 124 and the second liner 126, may be a surface that comes into contact with the first and second insulating structures IS1 and IS2. In other words, the first and second insulating structures IS1 and IS2 may directly contact one surface of the pad layer 140.

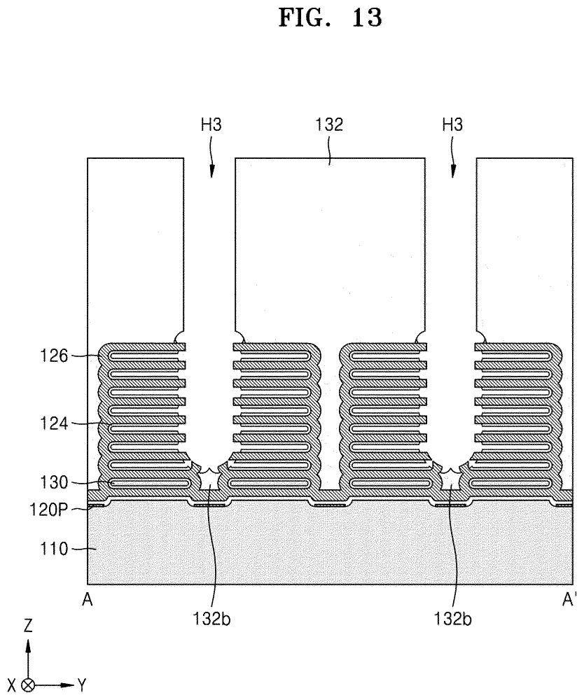

Lower surfaces of the first and second insulating structures IS1 and IS2 may be arranged at a vertical level higher than an upper surface of the substrate 110. That is, the first and second insulating structures IS1, IS2 may be physically separated from the substrate 110, and a single crystal semiconductor layer 130 instead of the pad layer 140 may be arranged at a vertical level lower than the first and second insulating structures IS1, IS2. This may be a result of a process of removing a portion of the single crystal semiconductor layers 130 exposed by a third hole H3 in a stack of the single crystal semiconductor layers 130 and filling, with the pad layer 140, a space from which some of the single crystal semiconductor layers 130 are removed (see FIG. 13). The single crystal semiconductor layers 130 disposed under the pad layer 140 may be surrounded on four sides by the first and second liners 124 and 126 and may not be electrically connected to the first and second insulating structures IS1, IS2. The single crystal semiconductor layer 130 may be arranged at a position overlapping the pad layer 140 from a planar perspective.

Each of the third word line pad portions WLE23, WLE33, WLE43, WLE53 may be formed in a mirror-symmetrical shape with respect to the first and second insulating structures IS1, IS2.

The pad layer 140 of FIG. 3 may correspond to the third word line pad portions WLE23, WLE33, WLE43, WLE53 of FIG. 2, and the first insulating structure IS1 and the second insulating structure IS2 of FIG. 3 may be components respectively corresponding to the first insulating structure IS1 and the second insulating structure IS2 of FIG. 2. In FIG. 3, the second word line pad portion WLE23 may be arranged on the left side of the first insulating structure IS1, and the third word line pad portions WLE33 may be arranged on the right side of the first insulating structure IS1. In FIG. 3, the fourth word line pad portions WLE43 may be arranged on the left side of the second insulating structure IS2, and the fifth word line pad portions WLE53 may be arranged on the right side of the second insulating structure IS2. In addition, the lower gap fill insulating layer 132U may be arranged between the third word line pad portions WLE33 and the fourth word line pad portions WLE43. In some embodiments, the lower gap fill insulating layer 132U may be formed integrally with a gap fill insulating layer 132 and may be a portion of the gap fill insulating layer 132 arranged at the same vertical level as the third word line pad portions WLE33 and the fourth word line pad portions WLE43. The second contact plug CMC2 may be arranged on the left side of the first insulating structure IS1, and the third contact plug CMC3 may be arranged on the right side of the first insulating structure IS1. The fourth contact plug CMC4 may be arranged on the left side of the second insulating structure IS2, and the fifth contact plug CMC5 may be arranged on the right side of the second insulating structure IS2.

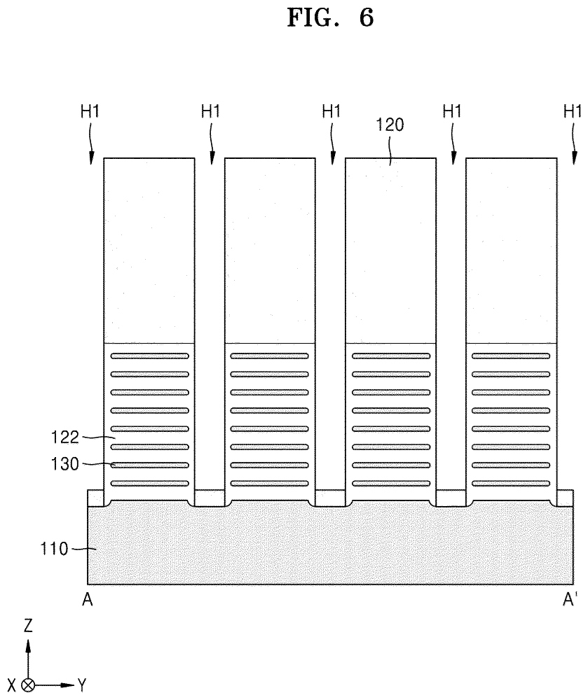

FIGS. 6 to 14 are cross-sectional views schematically illustrating a method of manufacturing a semiconductor device, according to an embodiment.

Referring to FIG. 6, a plurality of mold sacrificial layers 122 and a plurality of single crystal semiconductor layers 130 may be alternately stacked on the substrate 110, and then a cover insulating layer 120 may be formed thereon, and then a portion of the cover insulating layer 120 may be removed to form a plurality of first holes H1.

In embodiments, the process of forming the first holes H1 may be performed by an anisotropic etching process, and as illustrated in FIG. 6, the upper surface of the substrate 110 may not be exposed by the forming of the first holes H1. That is, bottom portions of the first holes H1 may be arranged at a vertical level higher than the upper surface of the substrate 110, and the upper surface of the substrate 110 may not be exposed by the cover insulating layer 120.

The substrate 110 may include a single crystal semiconductor material. For example, the substrate 110 may include a semiconductor material such as silicon (Si) or germanium (Ge).

Each of the plurality of mold sacrificial layers 122 and each of the plurality of single crystal semiconductor layers 130 may include a single crystal semiconductor material. The mold sacrificial layers 122 may include a semiconductor material having an etching selectivity with respect to the single crystal semiconductor layers 130. In some embodiments, the mold sacrificial layers 122 may have an etching selectivity with respect to the substrate 110. In some embodiments, the single crystal semiconductor layers 130 may include a material having the same or similar etching characteristics as the substrate 110.

In some embodiments, each of the plurality of mold sacrificial layers 122 may include silicon germanium (SiGe), and each of the plurality of single crystal semiconductor layers 130 may include silicon (Si). In other embodiments, each of the plurality of single crystal semiconductor layers 130 may include a single crystal two-dimensional (2D) material semiconductor or a single crystal oxide semiconductor material. For example, each of the plurality of single crystal semiconductor layers 130 may include a single layer or multiple layers of the single crystal oxide semiconductor material. In some embodiments, each of the plurality of single crystal semiconductor layers 130 may include a material having a band gap energy greater than the band gap energy of silicon (Si).

Each of the plurality of mold sacrificial layers 122 and each of the plurality of single crystal semiconductor layers 130 may be formed by a deposition process such as a chemical vapor deposition (CVD), a plasma enhanced CVD (PECVD), or an atomic layer deposition (ALD) process. In some embodiments, each of the plurality of mold sacrificial layers 122 and each of the plurality of single crystal semiconductor layers 130 may be formed in a single crystal state by using a layer in contact therewith as a seed layer, or may be formed in a single crystal state through a heat treatment process.

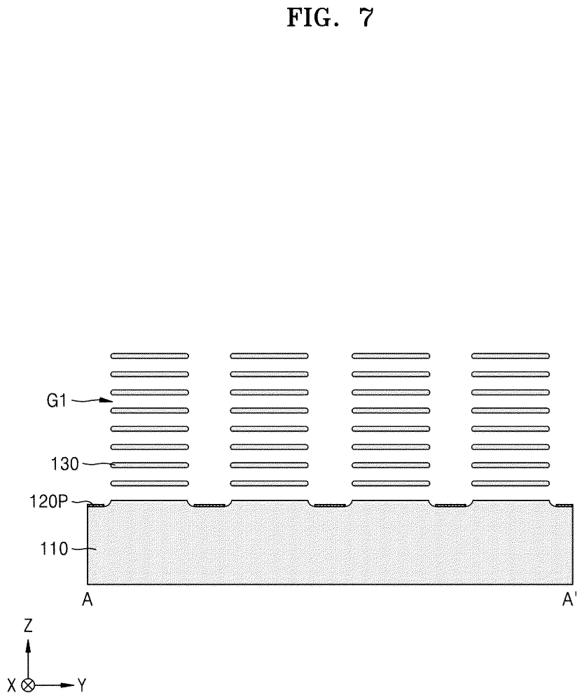

Referring to FIG. 7, a plurality of first gaps G1 may be formed between the plurality of single crystal semiconductor layers 130 by removing the plurality of mold sacrificial layers 122 through the plurality of first holes H1. The cover insulating layer 120 may also be removed, but a portion of the cover insulating layer 120, which is positioned under the first holes (H1, see FIG. 6) may not be removed and may remain on the substrate 110 as an insulating pad 120P. The plurality of first gaps G1 may be formed by removing the plurality of mold sacrificial layers 122 through an isotropic etching process with an etching selectivity with respect to the substrate 110 and the plurality of single crystal semiconductor layers 130.

In some embodiments, the isotropic etching process may be performed to remove portions of the plurality of single crystal semiconductor layers 130 to expand the plurality of first gaps G1. Accordingly, the horizontal width and vertical thickness of the plurality of single crystal semiconductor layers 130 may be reduced. However, the inventive concept is not limited thereto.

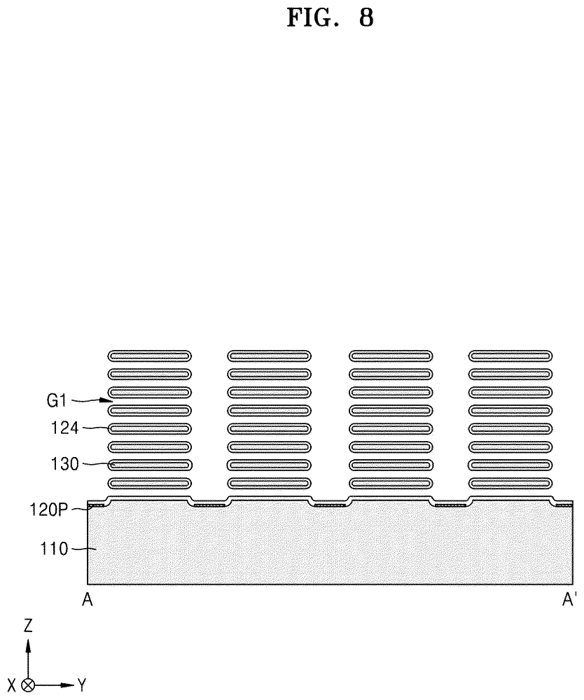

Referring to FIG. 8, the first liner 124 surrounding four sides of the plurality of single crystal semiconductor layers 130 may be formed in a resultant product of FIG. 7. The first liner 124 may be formed to cover, for each of the plurality of single crystal semiconductor layers 130, two sides of the plurality of single crystal semiconductor layers 130 in the second direction (Y direction) and two sides of the plurality of single crystal semiconductor layers 130 in the third direction (Z direction). In addition, the first liner 124 may also be formed on the upper surfaces of the substrate 110 and the insulating pad 120P. In embodiments, the first liner 124 may have a conformal thickness. In embodiments, the first liner 124 may include an insulating material, for example, an oxide.

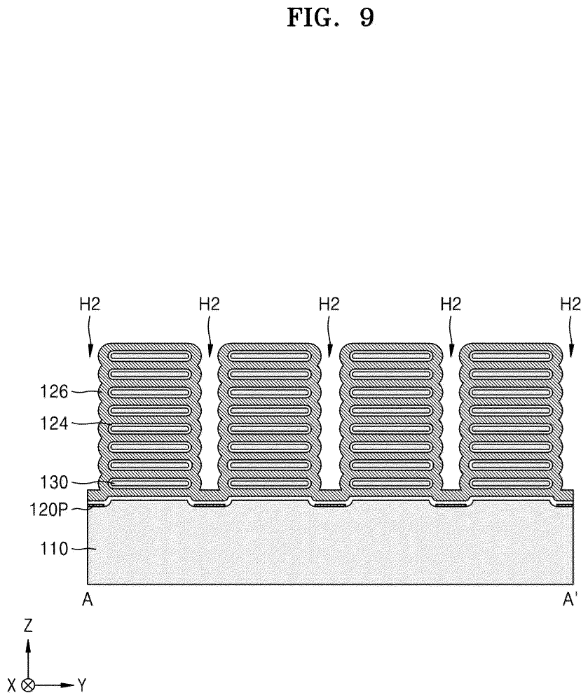

Next, referring to FIG. 9, the plurality of single crystal semiconductor layers 130 surrounded by the first liner 124 and the second liner 126 surrounding the upper surface of the substrate 110 may be formed. In embodiments, the second liner 126 may include SiN. By forming the second liner 126, all of the plurality of first gaps (G1, see FIG. 8) may be filled. That is, the second liner 126 may be formed to fill the entire space between the plurality of single crystal semiconductor layers 130 that are spaced apart from each other in the third direction (Z direction).

The plurality of single crystal semiconductor layers 130 spaced apart from each other in the third direction (Z direction) may be connected to one stack by the second liner 126, and the space between the stacks spaced apart from each other in the second direction (Y direction) may be referred to as a second hole H2. As illustrated in FIG. 9, side walls of the second hole H2 may be exposed side walls of the second liner 126, and a bottom surface of the second hole H2 may be an upper surface of the second liner 126 formed on the upper surface of the substrate 110.

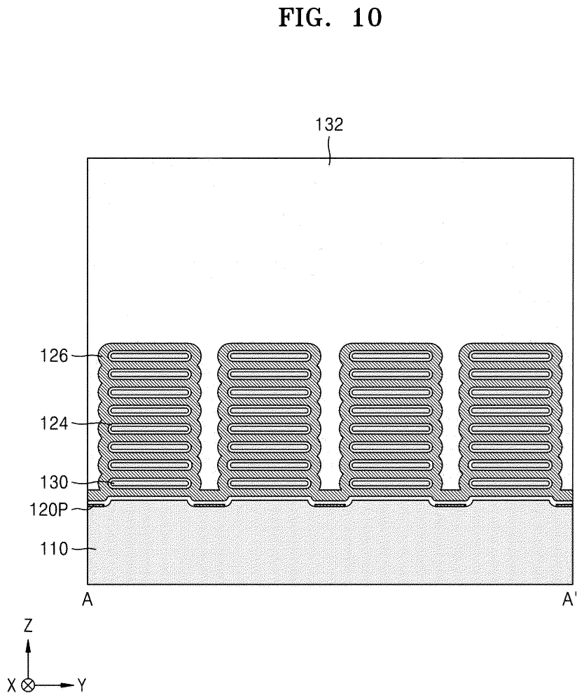

Referring to FIG. 10, the gap fill insulating layer 132 may be formed in a resultant product of FIG. 9. The gap fill insulating layer 132 may have a thickness large enough to cover the entire space between the second holes (H2, see FIG. 9) and cover the stacks arranged spaced apart from each other in the second direction (Y direction). In some embodiments, the gap fill insulating layer 132 of a bulk type, which has a relatively large thickness may be formed, and then a planarization process (e.g., a chemical mechanical polishing (CMP) process) may be performed to flatten an upper surface of the gap fill insulating layer 132.

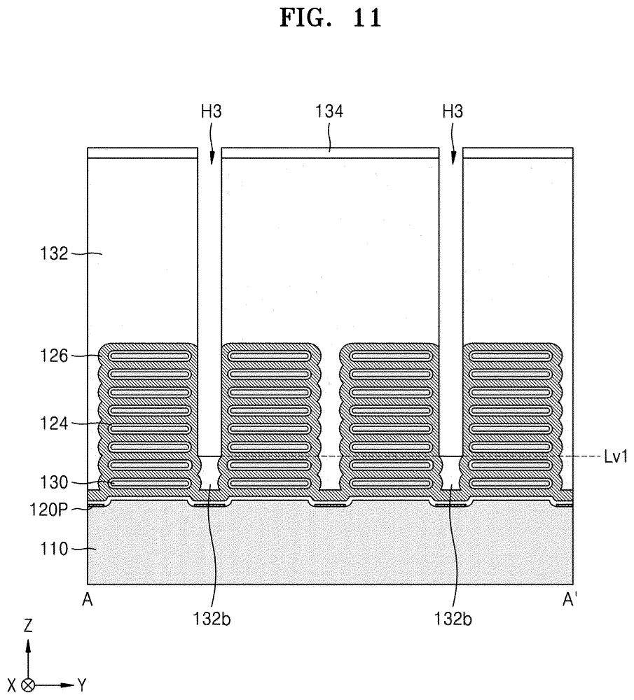

Referring to FIG. 11, after forming a gap fill liner 134 having a conformal thickness on the gap fill insulating layer 132, a plurality of third holes H3 may be formed by removing a portion of the gap fill liner 134 and the gap fill insulating layer 132. In embodiments, the gap fill liner 134 may include SiN.

As illustrated in FIG. 11, a vertical level of bottom surfaces of the plurality of third holes H3 may be a first level Lv1, and a height of the first level Lv1 may be greater than a height of the upper surface of the substrate 110. That is, in the process of removing a portion of the gap fill insulating layer 132 to form the plurality of third holes H3, at least a portion of the gap fill insulating layer 132 may be left unremoved, and thus, even if the plurality of third holes H3 are formed, the second liner 126 and the substrate 110 disposed below the third holes H3 may not be exposed. In embodiments, the first level Lv1 may be positioned at a vertical level that is higher than a vertical level of the upper surface of the substrate 110 and lower than the upper surface of the stacks.

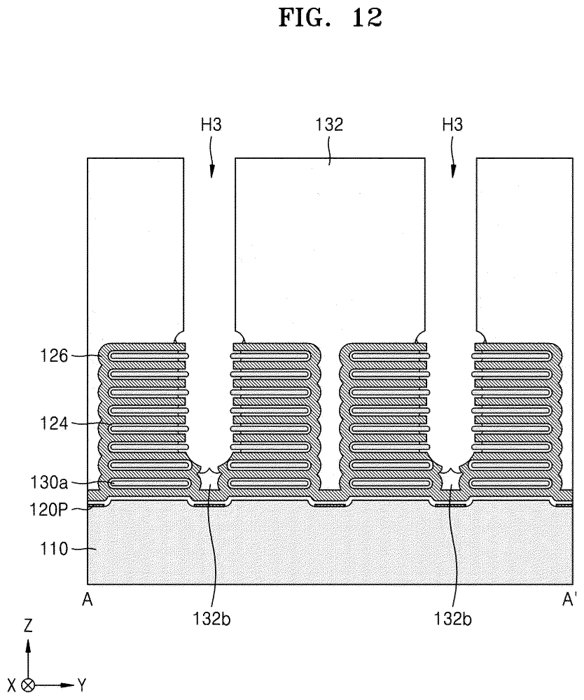

Referring to FIG. 12, a portion of the side walls of the second liner 126 exposed by the third holes H3 may be removed. In the above process, a portion of the first liner 124 facing side walls of the third hole H3 among the first liner 124 that surrounds the plurality of single crystal semiconductor layers 130 on four sides may also be removed. However, during this process, the plurality of single crystal semiconductor layers 130 may not be removed.

The gap fill insulating layer 132 disposed under the third holes H3 through the above process may have a portion that is etched toward the side walls of the third hole H3 and thus have an upper surface with a central portion protruding upward as illustrated in FIG. 12, and this may be referred to as a gap fill bottom portion 132b. Unlike the portions of each of the second liner 126 and the first liner 124 facing the side walls of the third hole H3, which are removed, the second liner 126 and the first liner 124 positioned at a vertical level lower than the first level (Lv1, see FIG. 11) are not exposed to the outside by the third holes H3, and thus portions thereof may remain without being removed.

As the portions of each of the second liner 126 and the first liner 124 are removed, the second liner 126 and the first liner 124 may have a ‘C’ shaped cross-section in a plane formed by the second direction (Y direction) and the third direction (Z direction).

Referring to FIG. 13, the single crystal semiconductor layers 130 exposed by the side wall of the third hole H3 may be removed. In this case, unlike a case where the single crystal semiconductor layers 130 facing the side walls of the third holes H3 are removed, the single crystal semiconductor layers 130 positioned at a vertical level lower than the first level (Lv1, see FIG. 11) may remain without being removed since they are not exposed to the outside by the third holes H3.

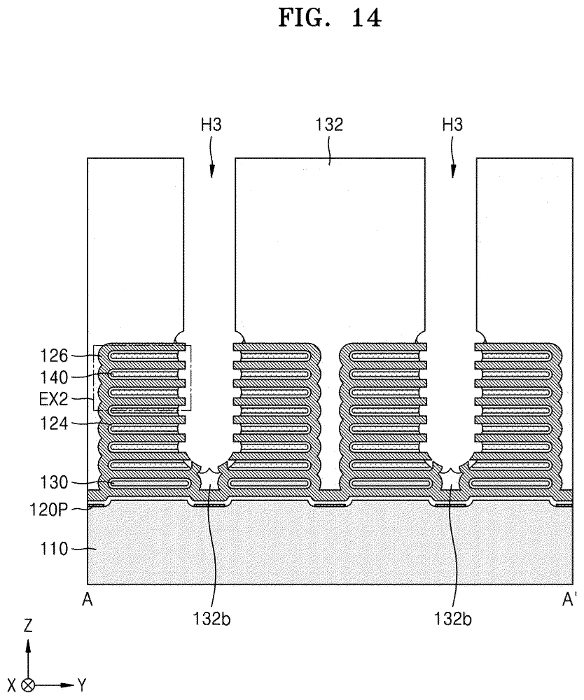

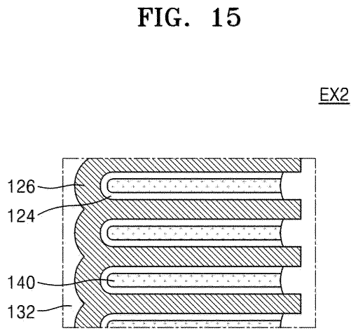

Referring to FIG. 14 together with FIG. 15, which is an enlarged cross-sectional view of region EX2 of FIG. 14, the pad layer 140 may be formed at a location from which the single crystal semiconductor layers 130 have been removed. The pad layer 140 may correspond to the third word line pad portions WLE23, WLE33, WLE43, WLE53 of FIG. 2. In embodiments, the pad layer 140 may include a component corresponding to the third word line pad portions WLE23, WLE33, WLE43, WLE53 described with reference to FIG. 2 and thus include a metal material. Although not shown in the cross-sectional view of the present specification, a process of removing a gate insulating layer (not shown) before forming the pad layer 140 may be further included.

Next, by filling the plurality of third holes H3 with an insulating material to form the second insulating structure IS2 and a third insulating structure IS3, respectively, and then forming the second to fifth contact plugs CMC2, CMC3, CMC4, CMC5 in contact with the third word line pad portions WLE23, WLE33, WLE43, WLE53, the semiconductor device 100 of FIG. 3 may be formed. The first insulating structure IS1 and the second insulating structure IS2 of FIG. 3 may be components respectively corresponding to the first insulating structure IS1 and the second insulating structure IS2 of FIG. 2. In some embodiments, a portion of the gap fill insulating layer 132, which is arranged at the same vertical level as the third word line pad portion WLE33 and the fourth word line pad portion WLE43 between the third word line pad portion WLE33 and the fourth word line pad portion WLE43, among the gap fill insulating layer 132, may be referred to as the lower gap fill insulating layer 132U.

As described above, the semiconductor device 100 may be manufactured.

In general, in the process of manufacturing semiconductor devices with a high number of stacks, there is a high risk of occurrence of tier-by-tier dispersion defects when performing an etching process on structures with a relatively large aspect ratio. However, in the semiconductor device 100 described with reference to FIGS. 1 to 15, by utilizing the gap fill insulating layer 132 as an etching stop layer, a constant open level may be maintained even when etching is performed on a relatively high number of stacks, and thus damage is not caused to the single crystal semiconductor layers 130 (see FIG. 11), and the pad layer 140 formed later may have a constant width in the second direction (Y direction) regardless of the tier. That is, by stably securing the area where the pad layer 140 is to be formed, the possibility of contact failure may be reduced, and thus the semiconductor device 100 with excellent electrical reliability may be provided.

Referring to FIG. 15, the first liner 124 is between the pad layer 140 and the second liner 126 that surrounds the pad layer 140 in a ‘C’ shape. That is, a liner covering the pad layer 140 may be formed in a double structure. Below, another embodiment may be described, in which a single layer of liner surrounds the pad layer 140.

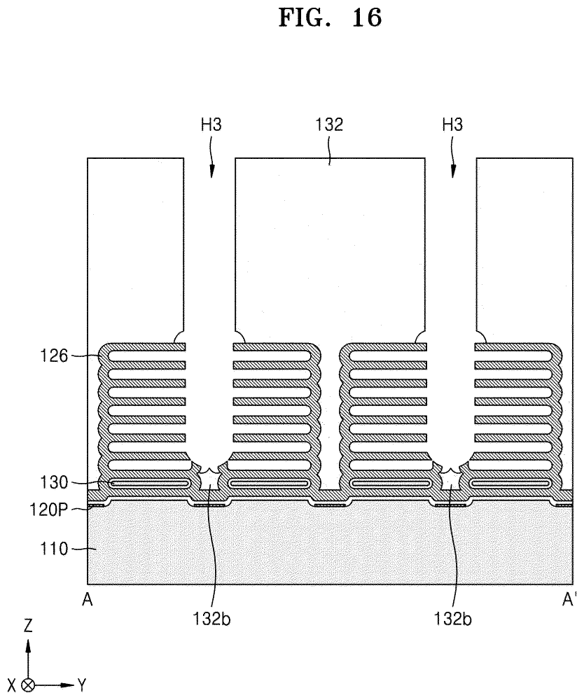

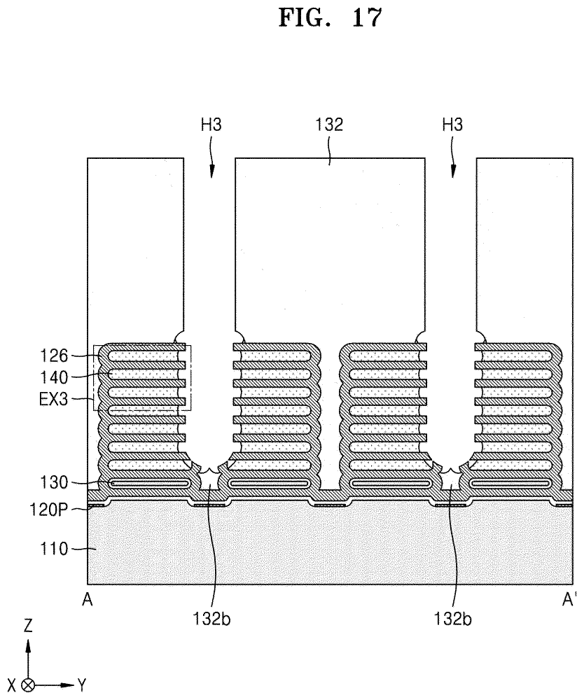

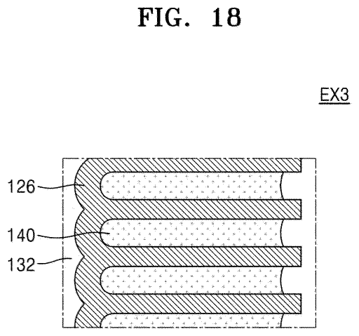

Referring to FIG. 16, the first liner 124 exposed by the side walls of the third holes H3 in a resultant product of FIG. 13 may be removed. Next, referring to FIG. 17 and FIG. 18, which is an enlarged view of region EX3 of FIG. 17, the pad layer 140 may fill a space where the first liner 124 and the single crystal semiconductor layer 130 are arranged, i.e., the space surrounded by the second liner 126. The pad layer 140 of FIG. 16 includes substantially the same material as the pad layer 140 described above, and thus a detailed description thereof may be omitted.

Comparing region EX3 of FIG. 18 with region EX2 of FIG. 15, it may be confirmed that in the semiconductor device 100 of FIG. 15, two layers of liners (the first liner 124 and the second liner 126) surround the pad layer 140, whereas in the semiconductor device 100 of FIG. 18, one layer of liner (the second liner 126) surrounds the pad layer 140.

Next, by forming an insulating material filling the plurality of third holes H3 in FIG. 17, the first insulating structure IS1 and the second insulating structure IS2 respectively corresponding to the first insulating structure IS1 and the second insulating structure IS2 of FIG. 2 may be formed, and the second to fifth contact plugs CMC2, CMC3, CMC4, CMC5 respectively falling on the third word line pad portions WLE23, WLE33, WLE43, WLE53 may be formed, and accordingly, the semiconductor device 100a according to the inventive concept may be manufactured. In some embodiments, a portion of the gap fill insulating layer 132 that is arranged at the same vertical level as the third word line pad portion WLE33 and the fourth word line pad portion WLE43 between the third word line pad portion WLE33 and the fourth word line pad portion WLE43, among the gap fill insulating layer 132, may be referred to as the lower gap fill insulating layer 132U.

Although the first liner 124 including an oxide and the second liner 126 including SiN are described in the present specification, this is an example, and the composition of the first and second liners 124 and 126 is not limited thereto. The first and second liners 124 and 126 may include another material having an etching selectivity with respect to Si included in the plurality of single crystal semiconductor layers 130.

Additionally, although not illustrated in this specification, in another embodiment where a single layer of liner surrounds the pad layer 140, a semiconductor device may also be manufactured, in which the first liner 124 is not formed from the beginning. That is, the process of forming the first liner 124 covering the four sides of the single crystal semiconductor layer 130 (see FIG. 8) may be omitted and the second liner 126 may be formed (see FIG. 9), and by performing the subsequent processes in the same manner as the manufacturing process of the semiconductor device 100 described above with reference to FIGS. 10 to 14, a semiconductor device including a single layer of liner may be obtained.

As described above, the embodiments have been disclosed in the drawings and specification.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
forming a laminated stack including a plurality of alternately stacked mold sacrificial layers and single crystal semiconductor layers, on an interface area of a substrate comprising a cell array area and the interface area disposed on at least one side of the cell array area;
forming a cover insulating layer covering the laminated stack, and then removing a portion of the cover insulating layer, to form a plurality of first holes;
forming a plurality of first gaps between the plurality of single crystal semiconductor layers by removing the plurality of mold sacrificial layers through the plurality of first holes, and forming a first liner surrounding the plurality of single crystal semiconductor layers;
forming a second liner on the first liner, to fill the first gaps;
forming a gap fill insulating layer surrounding the plurality of first holes and the laminated stack, and removing a portion of the gap fill insulating layer to form a plurality of second holes;
removing portions of the single crystal semiconductor layers, the portions facing side walls of the plurality of second holes;
forming a pad layer at a location from which the single crystal semiconductor layers are removed; and
filling the plurality of second holes with an insulating material,
wherein the pad layer has a step-like structure in a first direction parallel to an upper surface of the substrate, has a constant width in a second direction intersecting the first direction, and is connected to a word line arranged in the cell array area.

2. The method of claim 1, wherein the first liner and the second liner each comprise a material having etching selectivity with respect to a material included in the single crystal semiconductor layers.

3. The method of claim 1, wherein the first liner comprises an oxide and the second liner comprises silicon nitride (SiN).

4. The method of claim 1, wherein bottom surfaces of the plurality of second holes are arranged at a vertical level higher than the upper surface of the substrate.

5. The method of claim 1, wherein the removing of the single crystal semiconductor layers further comprises removing portions of the first liner and the second liner that are exposed by the second holes.

6. The method of claim 5, wherein the first liner and the second liner surround the pad layer in a ‘C’ shaped configuration.

7. The method of claim 6, wherein a length of the second liner in the second direction is greater than a length of the first liner in the second direction.

8. The method of claim 1, wherein the removing of the single crystal semiconductor layers further comprises removing all of the first liner and a portion of the second liner, which are exposed by the second holes.

9. The method of claim 8, wherein the second liner surrounds the pad layer in a ‘C’ shaped configuration.

10. The method of claim 1, further comprising forming a contact that is in contact with an upper surface of the pad layer, by removing a portion of the gap fill insulating layer.

11. The method of claim 1, wherein a length of the pad layer in the second direction is less than a length of the second liner in the second direction.

12. A method of manufacturing a semiconductor device, the method comprising:
forming a laminated stack including a plurality of alternately stacked mold sacrificial layers and single crystal semiconductor layers, on an interface area of a substrate comprising a cell array area and the interface area disposed on at least one side of the cell array area;
forming a cover insulating layer covering the laminated stack, and then removing a portion of the cover insulating layer, to form a plurality of first holes;
removing the plurality of mold sacrificial layers through the plurality of first holes and forming a liner surrounding the plurality of single crystal semiconductor layers and spaces between the plurality of single crystal semiconductor layers;
forming a gap fill insulating layer surrounding the plurality of first holes and the laminated stack, and removing a portion of the gap fill insulating layer, to form a plurality of second holes;
removing portions of the single crystal semiconductor layers, the portions facing side walls of the plurality of second holes;
forming a pad layer at a location from which the single crystal semiconductor layers are removed; and
filling the plurality of second holes with an insulating material,
wherein the pad layer has a step-like structure in a first direction parallel to an upper surface of the substrate, has a constant width in a second direction intersecting the first direction, and is connected to a word line arranged in the cell array area.

13. The method of claim 12, wherein the liner comprises a single layer.

14. The method of claim 12, wherein the removing of the single crystal semiconductor layers further comprises removing a portion of the liner exposed by the second holes.

15. The method of claim 12, wherein the liner surrounds the pad layer in a ‘C’ shaped configuration.

16. The method of claim 12, wherein bottom surfaces of the plurality of second holes are arranged at a vertical level higher than the upper surface of the substrate.

17. The method of claim 12, wherein a length of the pad layer in the second direction is less than a length of the liner in the second direction.

18. A method of manufacturing a semiconductor device, the method comprising:
forming a laminated stack including a plurality of alternately stacked mold sacrificial layers and single crystal semiconductor layers, on an interface area of a substrate comprising a cell array area and the interface area disposed on at least one side of the cell array area;
forming a cover insulating layer covering the laminated stack, and then removing a portion of the cover insulating layer, to form a plurality of first holes;
forming a plurality of first gaps between the plurality of single crystal semiconductor layers by removing the plurality of mold sacrificial layers through the plurality of first holes, and forming a first liner surrounding the plurality of single crystal semiconductor layers;
forming a second liner on the first liner, to fill the first gaps;
forming a gap fill insulating layer surrounding the plurality of first holes and the laminated stack, and forming a plurality of second holes by removing a portion of the gap fill insulating layer up to a first level higher than a level of an upper surface of the substrate;
removing at least some portions of the first liner and the second liner, the portions facing side walls of the plurality of second holes, and removing the single crystal semiconductor layers arranged at a level equal to or higher than the first level;
forming a pad layer at a location from which the single crystal semiconductor layers are removed; and
filling the plurality of second holes with an insulating material,
wherein the pad layer has a step-like structure in a first direction parallel to the upper surface of the substrate, has a constant width in a second direction intersecting the first direction, and is connected to a word line arranged in the cell array area.

19. The method of claim 18, wherein the pad layer is arranged at a level equal to or higher than the first level.

20. The method of claim 18, wherein the removing of the single crystal semiconductor layers further comprises removing all of the first liner.
